(19) United States
(12) Patent Application Publication
(10) Pub. No.: US 2010/0002493 A1
(43) Pub. Date: Jan. 7, 2010

(54) SEMICONDUCTOR STORAGE DEVICE

(75) Inventors: Tadashi Miyakawa, Yokohama-shi (JP); Daisaburo Takashima, Yokohama-shi (JP)

Correspondence Address: KNOBBE MARTENS OLSON & BEAR LLP, 2040 MAIN STREET, FOURTEENTH FLOOR, IRVINE, CA, 92614, US

(73) Assignee: KABUSHIKI KAISHA TOSHIBA, Tokyo (JP)

(21) Appl. No.: 12/497,623

(22) Filed: Jul. 3, 2009

(30) Foreign Application Priority Data
Jul. 4, 2008 (JP) P2008-176017

(51) Int. Cl. G11C 11/24; G11C 7/06; G11C 7/00; G11C 5/14; G11C 7/02

(52) U.S. Cl. 365/149; 365/203; 365/189.09; 365/189.07; 365/210.1

(57) ABSTRACT

A precharge circuit precharges a bit line paired with the bit line to which the selected one of the memory cells is connected, by applying to the former bit line an external reference voltage for comparison with a voltage in the bit line caused by selection of the memory cell. A precharge assist circuit, which is connected to the former bit line in parallel with the precharge circuit, charges the bit line to a predetermined potential by using a power supply voltage. A sense amplifier, which is connected to the pair of bit lines, senses and amplifies a potential of a bit line that is connected to a memory cell selected by word lines.

### CROSS REFERENCE TO RELATED APPLICATIONS

This application is based on and claims the benefit of priority from prior Japanese Patent Application No. 2008-176017, filed on Jul. 4, 2008, the entire contents of which are incorporated herein by reference.

### BACKGROUND OF THE INVENTION

1. Field of the Invention

The present invention relates to a semiconductor storage device, and in particular, to a memory test circuit for measuring distribution characteristics of the amount of cell signals in memory cells.

2. Description of the Related Art

Conventionally, in test mode for measuring the distribution of the amount of cell signals in memory cells, some methods have been used that measure the distribution of the mount of cell signals, by inputting a reference voltage, which is to be compared with the bit line voltage caused by a memory cell signal, to a complementary bit line from the outside world, performing a read operation by a sense amplifier, and changing the reference voltage on a step-by-step basis (see, for example, Japanese Patent No. 3425916).

However, such methods of measuring the distribution of the amount of cell signals in memory cells in test mode have problems that it may take a very long time to charge a plurality of bit lines at the same time with a reference voltage during the standby mode before all of the bit lines are charged to a predetermined potential, which leads to an increase in test time.

While the standby time lasts for several tens of nanoseconds in normal read operation, setting the bit lines to the reference voltage in test mode will take several hundreds of nanoseconds to several milliseconds. The latter standby time is about 10 to 100 times longer than is required for the normal read operation. Thus, it will take even several hours per chip to measure the amount of cell signals in all memory cells by changing the reference voltage.

### SUMMARY OF THE INVENTION

One aspect of the present invention provides a semiconductor storage device comprising: a plurality of memory cells, each including a capacitor to retain data; a plurality of word lines selecting the memory cells; a bit line reading a signal in one of the memory cells selected by the word lines; a precharge circuit configured to precharge another bit line paired with the bit line to which the selected one of the memory cells is connected, by applying to the other bit line an external reference voltage for comparison with a voltage in the bit line caused by selection of the memory cell; a precharge assist circuit connected to the other bit line in parallel with the precharge circuit, the precharge assist circuit charging the other bit line to a predetermined potential by using a power supply voltage; and a sense amplifier connected to the pair of bit lines, the sense amplifier sensing and amplifying a potential of a bit line connected to a memory cell selected by the word lines.

Another aspect of the present invention provides a semiconductor storage device comprising: a plurality of memory cells, each including a capacitor to retain data; a plurality of word lines selecting the memory cells; a bit line reading a signal in one of the memory cells selected by the word lines; a precharge circuit precharging another bit line paired with the bit line to which the selected one of the memory cells is connected, by applying to the other bit line an external reference voltage for comparison with a voltage in the bit line caused by selection of the memory cell; a dummy cell circuit including dummy cells connected in series between the pair of bit lines, each of the dummy cells having one transistor and one capacitor; and a sense amplifier connected to the pair of bit lines, the sense amplifier sensing and amplifying a potential of a bit line connected to a memory cell selected by the word lines, the other bit line being charged to a predetermined potential with a dummy-cell reference voltage supplied to the dummy cells before being charged by the precharge circuit.

Still another aspect of the present invention provides a semiconductor storage device comprising: a plurality of memory cells, each including a capacitor to retain data; a plurality of word lines for selecting the memory cells; a bit line for reading a signal in one of the memory cells selected by the word lines; a precharge circuit configured to precharge another bit line paired with the bit line to which the selected one of the memory cells is connected, by applying to the other bit line an external reference voltage for comparison with a voltage in the bit line caused by selection of the memory cell; a stress reduction circuit including two MOS transistors connected in series between the pair of bit lines; and a sense amplifier connected to the pair of bit lines, the sense amplifier sensing and amplifying a potential of a bit line connected to a memory cell selected by the word lines, the other bit line being charged to a predetermined potential with a stress reduction voltage supplied to the stress reduction circuit before being charged by the precharge circuit.

### BRIEF DESCRIPTION OF THE DRAWINGS

FIG. 1 is a circuit diagram of a semiconductor storage device according to a first embodiment of the present invention;

FIG. 2 illustrates a circuit configuration of a pair of bit lines in a memory cell array of the semiconductor storage device according to the first embodiment of the present invention;

FIG. 3 illustrated a circuit configuration of a pair of bit lines in a memory cell array of a conventional semiconductor storage device;

FIG. 4 illustrates a specific example of a circuit configuration of the semiconductor storage device according to the first embodiment of the present invention;

FIG. 5 illustrates a specific example of a circuit configuration of the conventional semiconductor storage device;

FIG. 6A illustrates a relationship between change in external reference voltage Vdr and output signals from a sense amplifier;

FIG. 6B is a graph illustrating a relationship between the external reference voltage Vdr and the distribution of the amount of cell signals;

FIG. 7 is a graph illustrating the external reference voltage Vdr and the distribution of the amount of cell signals in test mode;

FIG. 8 is a timing chart of test mode operation of the semiconductor storage device according to the first embodiment of the present invention;

FIG. 9 is a timing chart of test mode operation of the conventional semiconductor storage device;

FIG. 10 illustrates a specific example of a circuit configuration of a semiconductor storage device according to a second embodiment of the present invention;

FIG. 11 is a timing chart of test mode operation of the semiconductor storage device according to the second embodiment of the present invention;

FIG. 12 illustrates a circuit configuration of a pair of bit lines in a memory cell array of a semiconductor storage device according to a third embodiment of the present invention;

FIG. 13 illustrates a specific example of a circuit configuration of the semiconductor storage device according to the third embodiment of the present invention; and

FIG. 14 is a timing chart of test mode operation of the semiconductor storage device according to the third embodiment of the present invention.

### DETAILED DESCRIPTION OF THE EMBODIMENTS

Embodiments of a semiconductor storage device according to the present invention will now be described in detail below with reference to the accompanying drawings.

### First Embodiment

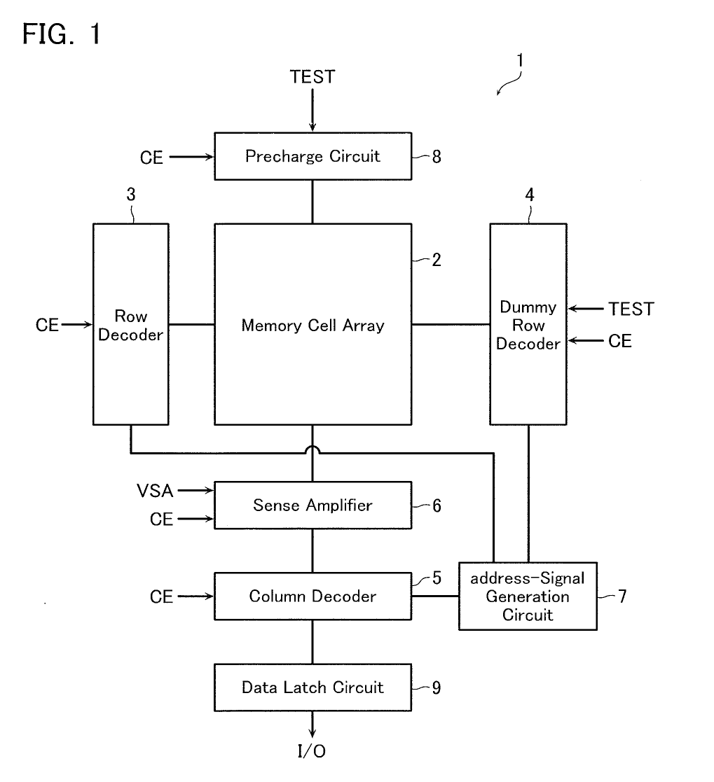

FIG. 1 is a block diagram of a semiconductor storage device according to a first embodiment of the present invention. The semiconductor storage device 1 according to the first embodiment comprises: a memory cell array 2; a row decoder 3; a dummy row decoder 4; a column decoder 5; a sense amplifier 6; an address-signal generation circuit 7; a precharge circuit 8; and a data latch circuit 9.

For example, the memory cell array 2 includes memory cells, each having one transistor and one capacitor and provided at an intersection between a word line WL and one of a pair of bit lines BL0, BL1, thereby providing cell arrays in a matrix form.

The memory cell array 2 is connected to the row decoder 3. The row decoder 3 generates a word-line selection signal SWL to select a memory cell, in response to a chip enable signal CE and an address signal from the address-signal generation circuit 7. The column decoder 5 generates a signal for driving a selection gate transistor in response to an address signal. The column decoder 5 then selects and activates the pair of bit lines BL0, BL1.

The memory cell array 2 is connected to the sense amplifier 6. The sense amplifier 6, which is activated by a sense-amplifier activation signal VSA, senses and amplifies the voltage of the pair of bit lines BL0, BL1 selected by the column decoder 5. The sense amplifier 6 then reads data retained in the memory cell and outputs “0” or “1” data. The read data is retained at the data latch circuit 9, and then output through the I/O interface.

The memory cell array 2 is also connected to the dummy row decoder 4. The dummy row decoder 4 selects a dummy cell in response to a chip enable signal CE and a test initiation signal TEST for test mode described below, as well as to an address signal from the address-signal generation circuit 7.

The memory cell array 2 is further connected to the precharge circuit 8. In response to the chip enable signal CE and the test initiation signal TEST for test mode, the precharge circuit 8 precharges, in test mode, the potential of one of the pair of bit lines BL0, BL1 selected by the column decoder 5 with an external reference voltage described below.

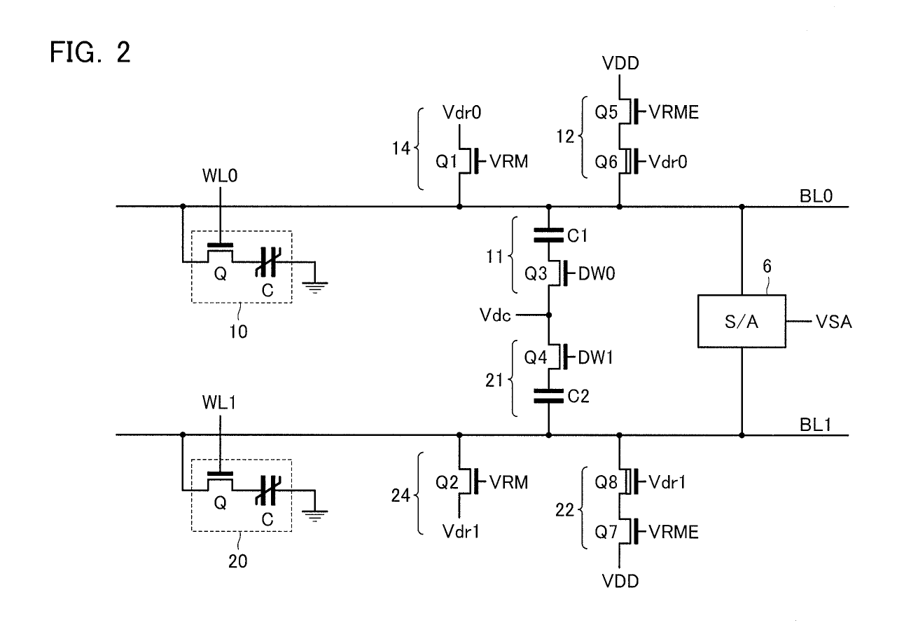

FIG. 2 representatively illustrates one pair of bit lines BL0, BL1 in the memory cell array 2 illustrated in FIG. 1. The bit lines BL0 and BL1 are each connected to a memory cell 10 and a memory cell 20. Each of the memory cells 10 and 20 includes, for example, a 1T/1C-type cell that has one transistor Q and one capacitor C. It should be noted that the memory cells are not limited to this configuration.

Word lines WL0 and WL1 are connected to the row decoder 3, and word signals SWL0 and SWL1 are provided to one of the word lines selected by the row decoder 3.

The pair of bit lines BL0, BL1 is activated by the column decoder 5. The bit line BL0 is connected to a precharge circuit 14 for precharging the potential of the bit line BL0 in test mode as described in detail below. The precharge circuit 14 includes, for example, an NMOS transistor Q1 with a source electrode connected to the corresponding bit line. In test mode, an external reference voltage Vdr0, which is to be compared with the voltage of the bit line BL1 when reading the signal in the memory cell 20, is applied to the drain electrode of the transistor Q1. A precharge signal VRM is applied to the gate electrode of the transistor Q1. The precharge signal VRM is set to Vdr0+Vth (where Vth represents a threshold voltage of the transistor Q1) for switching the transistor Q1 or more. When the transistor Q1 turns on, the external reference voltage Vdr0 is supplied to the bit line BL0 and the bit line BL0 is precharged.

The other of the pair of bit lines, i.e., the bit line BL1 is connected to a precharge circuit 24 for precharging the potential of the bit line BL1 in test mode. The precharge circuit 24 includes, for example, an NMOS transistor Q2 with a source electrode connected to the corresponding bit line. In test mode, an external reference voltage Vdr1, which is to be compared with the voltage of the bit line BL0 when reading the signal in the memory cell 10, is applied to the drain electrode of the transistor Q2. A precharge signal VRM is applied to the gate electrode of the transistor Q2. The precharge signal VRM is set to Vdr1+Vth (where Vth represents a threshold voltage of the transistor Q2) for switching the transistor Q2 or more. When the transistor Q2 turns on, the external reference voltage Vdr1 is supplied to the bit line BL1 and the bit line BL1 is precharged. The transistors Q1 and Q2 used herein may or may not have the same characteristics.

The bit line BL0 is also connected to a precharge assist circuit 12 for reducing the time taken for the precharge circuit 14 to precharge the bit line BL0 in test mode for reading the memory cell 20. The precharge assist circuit 12 includes, for example, two NMOS transistors Q5 and Q6 with different threshold voltages connected in series. The transistor Q6 has a threshold voltage that is designed to be lower than that of the transistor Q5. A power supply voltage VDD is applied to the drain electrode of the transistor Q5 with the higher threshold voltage, and the source electrode of the transistor Q6 with the lower threshold voltage is connected to the bit line BL0.

The transistor Q5 has a threshold voltage Vth1 of, e.g., 0.6V, while the transistor Q6 has a threshold voltage Vth2 of, e.g., 0.2V. A precharge assist signal VRME is applied to the gate of the transistor Q5, while the external reference voltage Vdr0 is applied to the gate of the transistor Q6.

Similarly, the bit line BL1 is connected to a precharge assist circuit 22 for reducing the time taken for the precharge circuit 24 to precharge the bit line BL1 in test mode for reading the memory cell 10. The precharge assist circuit 22 connected to the bit line BL1 includes, for example, two NMOS transistors Q7 and Q8 with different threshold voltages connected in series. The transistor Q8 has a threshold voltage that is designed to be lower than that of the transistor Q7. A power supply voltage VDD is applied to the drain electrode of the transistor Q7 with the higher threshold voltage, and the source electrode of the transistor Q8 with the lower threshold voltage is connected to the bit line BL1.

The transistor Q7 has a threshold voltage Vth1 of, e.g., 0.6V, while the transistor Q8 has a threshold voltage Vth2′ of, e.g., 0.2V. A precharge assist signal VRME is applied to the gate of the transistor Q7, while the external reference voltage Vdr1 is applied to the gate of the transistor Q8.

Two dummy cells 11 and 21 are connected in series between the pair of bit lines BL0, BL1. The dummy cell 11 includes, for example, a 1T/1C-type cell that has one NMOS transistor Q3 and one capacitor C1. Similarly, the dummy cell 21 includes, for example, a 1T/1C-type cell that has one NMOS transistor Q4 and one capacitor C2. A dummy cell voltage Vdc is applied to the drain electrodes of the transistors Q3 and Q4. Dummy word signals DW0 and DW1 that are output from a dummy-word-signal generation circuit as described in detail below are provided to the gate electrodes of the transistors Q3 and Q4 in the dummy cells 11 and 21. Each of the dummy cells 11 and 21 has a function for applying a reference voltage to the bit line. The reference voltage is an intermediate voltage between “L” or “H” level of the potential of the connected bit line in normal read operation. For example, when reading the memory cell 20, the dummy cell 11 is selected and a dummy-cell drive signal DW0 is provided to the transistor Q3. Then, the transistor Q3 turns on and the potential of the bit line BL0 becomes the reference voltage.

The sense amplifier 6 is connected between the pair of bit lines BL0, BL1. The sense amplifier 6 includes, for example, an NMOS flip-flop having two NMOS transistors and a PMOS flip-flop having two PMOS transistors, not illustrated. The distribution of the amount of cell signals in the memory cell array 2 may be obtained by activating the sense amplifier 6 in response to an activation signal VSA from a sense-amplifier-drive-signal generation circuit as described in detail below, then comparing and amplifying the bit line voltage and an external reference voltage when reading the memory cell 20 in test mode.

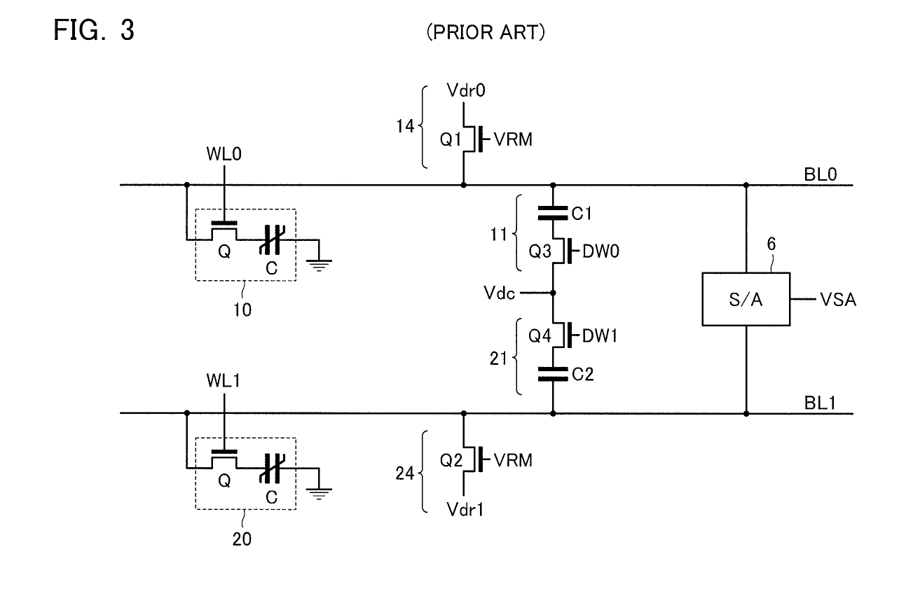

FIG. 3 illustrates a typical pair of bit lines in a memory cell array of a conventional semiconductor storage device. The same reference numerals represent the same components as the present invention mentioned above.

The conventional semiconductor storage device has precharge circuits 14 and 24, but does not have the above-mentioned precharge assist circuits 12 and 22. Thus, precharging the bit line BL0 takes a long time in test mode. The first embodiment of the present invention resolves this problem by providing the precharge assist circuits 12 and 22.

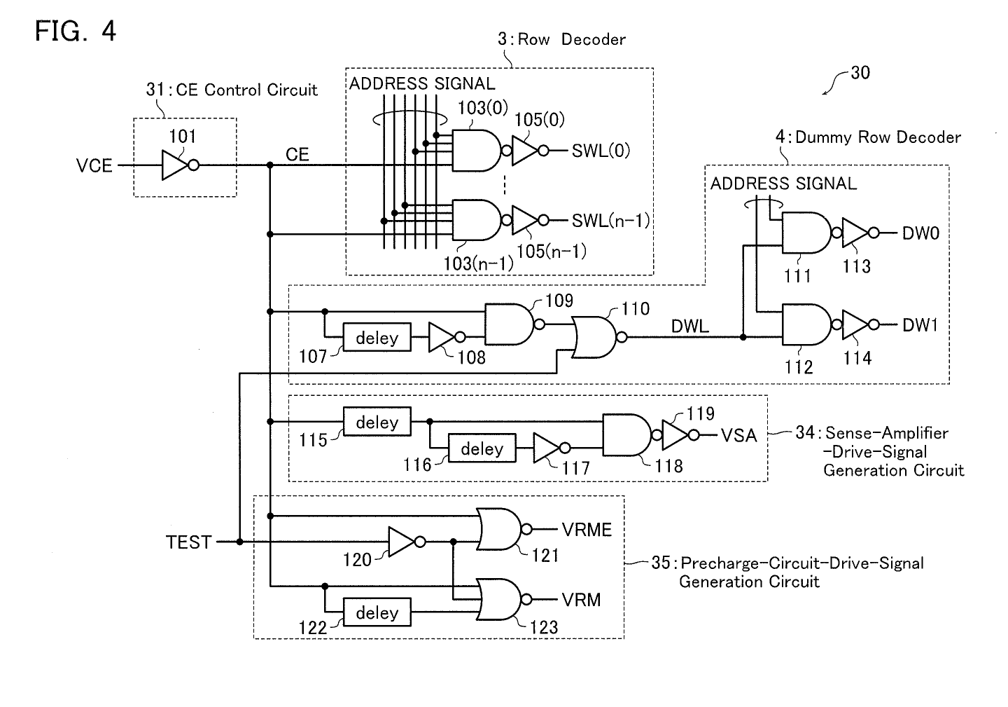

A specific circuit configuration of the semiconductor storage device according to the first embodiment of the present invention will be described below. FIG. 4 illustrates an example circuit configuration of the semiconductor storage device according to the first embodiment. The semiconductor storage device 30 according to the first embodiment comprises: a CE control circuit 31 that generates a chip enable signal CE; a row decoder 3 that generates a word signal; a dummy row decoder 4 that generates a dummy word signal; a sense-amplifier-drive-signal generation circuit 34; and a precharge-circuit-drive-signal generation circuit 35 that provides a drive signal to a precharge circuit 8.

The CE control circuit 31 outputs a chip enable signal CE resulting from inverting the input chip enable signal VCE through an inverter 101 and delaying it by a certain amount of time.

The row decoder 3 performs NAND operations, at NAND gates 103(0), . . . , 103(n−1), on the chip enable signal CE and an address signal from the address-signal generation circuit 7 (FIG. 1), the outputs of which are in turn inverted at inverters 105(0), . . . , 105(n−1) to generate word signals SWL0, . . . , SWL(n−1). As a result, a memory cell 10 that is connected to the word line WL supplied with a word signal SWLi (i=0 to (n−1)) as “H” is selected, whereas a memory cell that is connected to a word line WL supplied with a word signal SWLi as “L”.

First, at a NAND gate 109, the dummy row decoder 4 performs a NAND operation on a chip enable signal CE and another signal resulting from delaying the chip enable signal CE by a delay circuit 107 and then inverting it by an inverter 108. Then, at a NOR gate 110, it performs a NOR operation on the output from the NAND gate 109 and a test initiation signal TEST, thereby generating a dummy word line signal DWL. Subsequently, NAND operations are performed at NAND gates 111 and 112 on the dummy word line signal DWL and the address signal from the address-signal generation circuit 7, the outputs of which are in turn inverted at inverters 113 and 114 to generate dummy word signals DW0 and DW1.

The sense-amplifier-drive-signal generation circuit 34 delays the chip enable signal CE by a delay circuit 115. Then, at a NAND gate 118, it performs a NAND operation on the signal delayed by the delay circuit 115 and another signal resulting from further delaying the delayed signal by a delay circuit 116 and then inverting it by an inverter 117, the output of which is in turn inverted at an inverter 119 to generate a sense-amplifier activation signal VSA.

The precharge-circuit-drive-signal generation circuit 35 performs a NOR operation at a NOR gate 121 on the test initiation signal TEST inverted by an inverter 120 and the chip enable signal CE to generate a precharge assist signal VRME for driving the precharge assist circuits 12 and 22 (FIG. 2). In addition, at a NOR gate 123, it performs a NOR operation on the chip enable signal CE, and another signal resulting from delaying the chip enable signal CE by a delay circuit 122, and still another signal resulting from inverting the chip enable signal CE at the inverter 120, thereby generating a precharge signal VRM for driving the precharge circuits 14 and 24. The delay circuit 122 causes the precharge assist signal VRME to become “H” at an earlier time than the precharge signal VRM, and and causes the precharge assist circuits 12 and 22 to operate at an earlier time than the precharge circuits 14 and 24 to increase the potential of the bit lines. Consequently, this reduces the time taken for precharging the bit lines BL0 and BL1 to the external reference voltages Vdr0 and Vdr1.

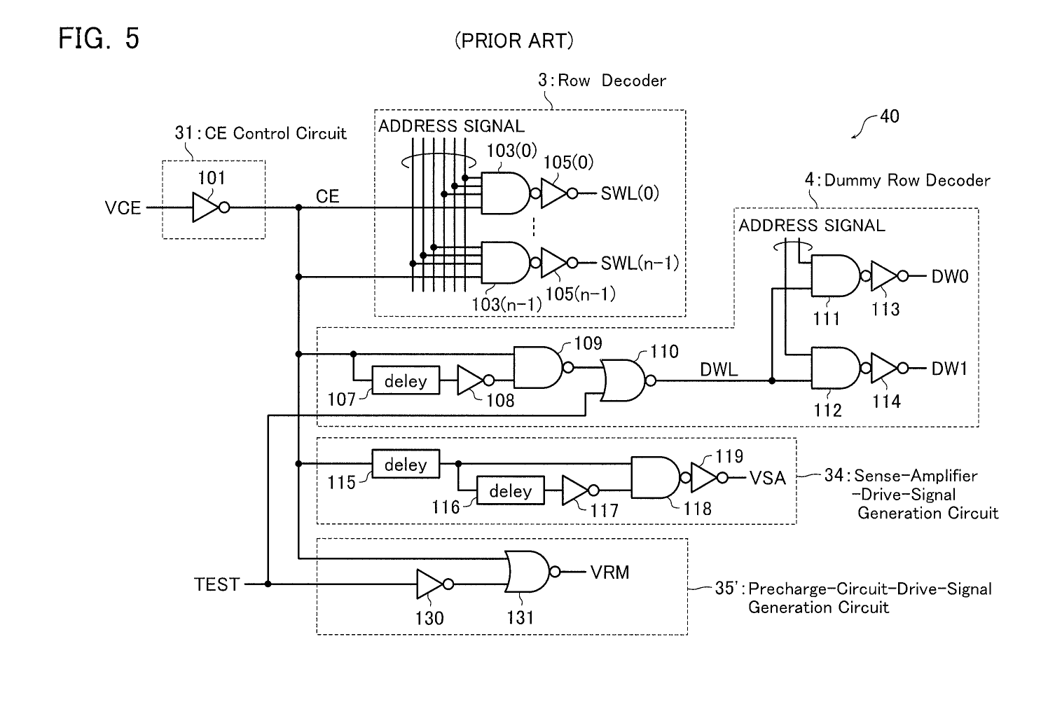

FIG. 5 illustrates a specific example of a circuit configuration of the conventional semiconductor storage device illustrated in FIG. 3. The same reference numerals represent the same components as the first embodiment illustrated in FIG. 4. The conventional circuit is different from the first embodiment only in the configuration of a precharge-circuit-drive-signal generation circuit 35′. The conventional precharge-circuit-drive-signal generation circuit 35′ only generates a precharge signal VRM and does not generate a precharge assist signals VRME. That is, the conventional precharge-circuit-drive-signal generation circuit 35′ performs a NOR operation at a NOR gate 131 on a chip enable signal CE and another signal resulting form inverting a test initiation signal TEST by an inverter 130, and only generates a precharge signal VRM for driving the precharge circuits 14 and 24.

The test mode will now be described in detail below with reference to the drawings. In test mode, the amount of cell signals in a memory cell is measured by directly reading a cell voltage Vcell read from the selected cell by the sense amplifier 6.

First, the selected memory cell is connected to a bit line, and the external reference voltage Vdr is applied to another bit line paired with the bit line connected to the selected memory cell. Then, the sense amplifier 6 detects, while changing a value of the external voltage Vdr, a specific value of the external voltage Vdr that reverses a magnitude relationship between the voltage Vcell obtained from the selected memory cell and the external reference voltage Vdr. This enables the distribution of the amount of cell signals in memory cells in the memory cell array 2 to be checked.

FIG. 6A illustrates a relationship between the external reference voltage Vdr that is applied to the bit line to which a non-selected memory cell is connected and the output data that is read from the selected memory cell and that is sensed and compared at a sense amplifier.

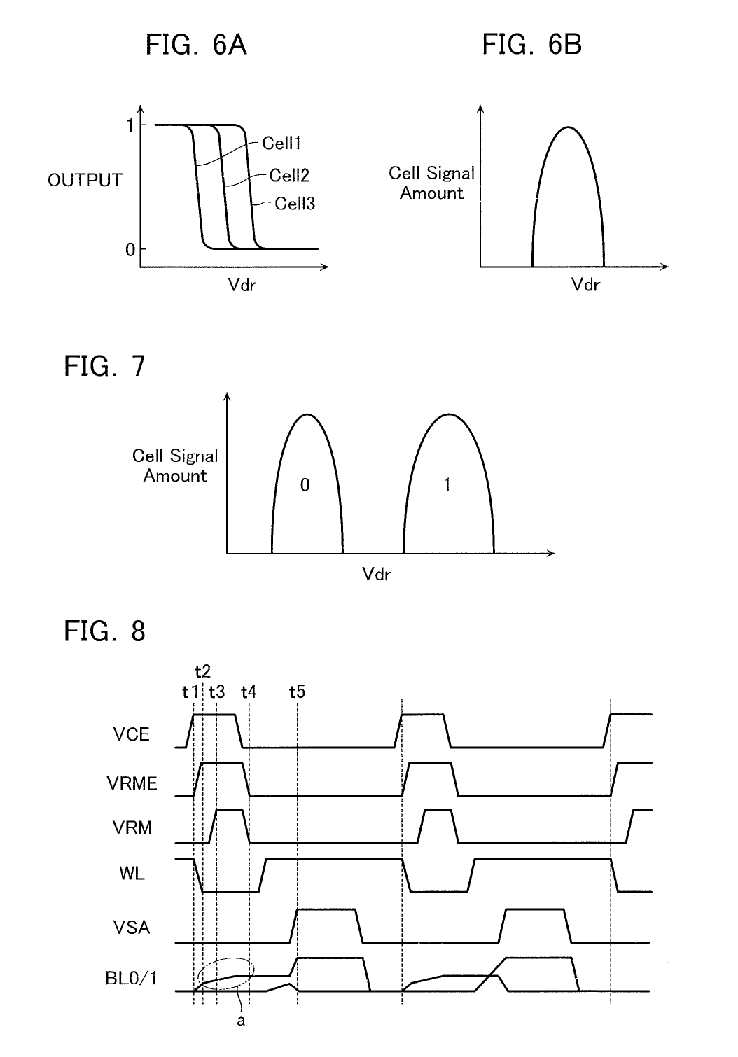

Specifically, if the external reference voltage Vdr is smaller than the cell voltage Vcell read from the selected memory cell, then the sense amplifier 6 outputs “1” data. Otherwise, if the external reference voltage Vdr is larger than the cell voltage Vcell read from the selected memory cell, then the sense amplifier 6 outputs “0” data. That is, the sense amplifier 6 determines that the output data is “1” for Vcell>Vdr and “0” for Vcell≦Vrd. The output of the sense amplifier 6 changes from “1” to “0”, or vice versa, depending on the change in the external reference voltage Vdr. The specific value of the external reference voltage Vdr when the output changes is considered as the amount of cell signals in the selected memory cell. The specific values of the external reference voltage Vdr are different from one memory cell to another (FIG. 6A) When measurement of the amount of the cell signals is conducted for the entire memory cell array, the amount of the cell signals has a certain distribution. FIG. 6B schematically illustrates the distribution of the amount of cell signals. Upon measuring the amount of cell signals when “0” is stored in all cells and when “1” is stored in all cells, such distribution is observed as illustrated in FIG. 7.

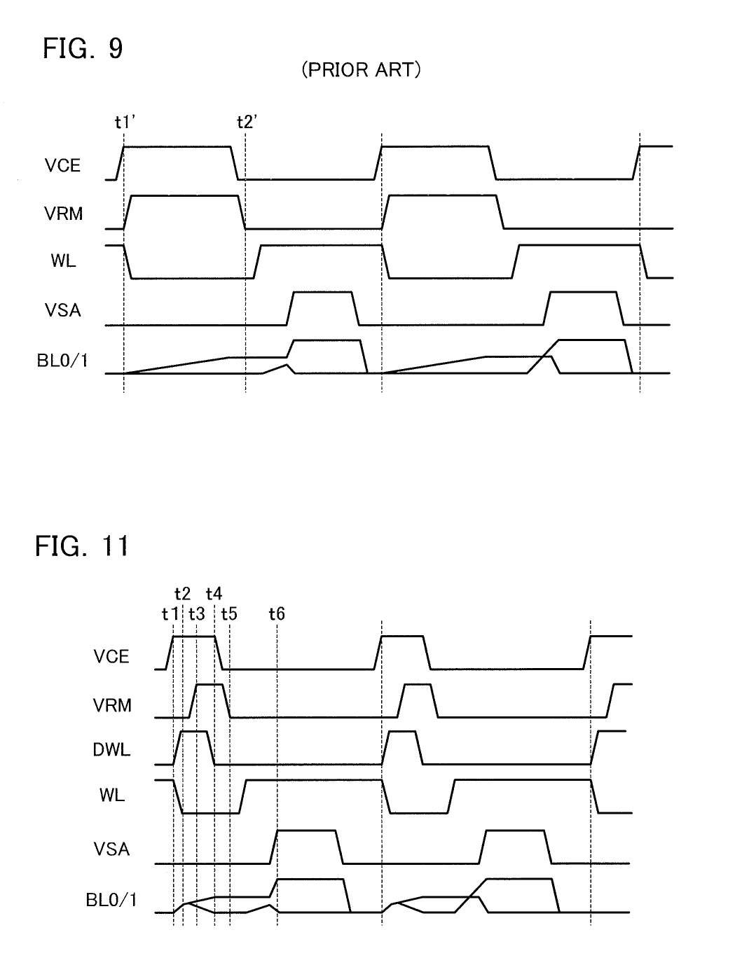

The operation of the semiconductor storage device 1 according to the first embodiment of the present invention will now be described in detail below with reference to the drawings. FIG. 8 is a timing chart illustrating the operation of the semiconductor storage device according to the first embodiment in test mode.

Firstly, at time t1, the chip enable signal VCE input to the CE control circuit 31 becomes “H” and the chip enters a standby state. Then, at time t2, the word signal SWL0 of the word line WL0 becomes “L” (non-selected) due to the word signal generated by the row decoder 3. At the same time, the precharge assist signal VRME generated by the precharge-circuit-drive-signal generation circuit 35 becomes “H”. As a result, the voltage of Vdr0−Vth1 is applied to the bit line BL0. In this case, Vth1 represents a threshold voltage of the transistor Q6. The transistor Q6 has a lower threshold voltage than that of the transistor Q5. Thus, the transistor Q6 switches fast to charge the bit line BL0 to the voltage of Vdr0−Vth1.

Subsequently, at time t3, the precharge signal VRM generated by the precharge-circuit-drive-signal generation circuit 35 becomes “H”, and the transistor Q1 turns on to charge the bit line BL0 from Vdr0−Vth1 to Vdr0. As indicated by the dotted line “a”, since the bit line BL0 will already be charged to the voltage of Vdr0−Vth1 at this point, the precharge circuit 14 needs only to charge voltage of Vth1. Consequently, this reduces the charging time as compared with the conventional art. The first embodiment is thus characterised in that it reduces the time taken for precharging the bit line BL0 by charging the bit line BL0 to the voltage of Vdr0−Vth1 with the precharge assist circuit 12 at a time slightly before the bit line BL0 is precharged by the precharge circuit 14.

Thereafter, the chip enable signal CE generated by the CE control circuit 31 becomes “L” and the chip enters an active state. Then, at time t4, both the precharge assist signal VRME and precharge signal VRM generated by the precharge-circuit-drive-signal generation circuit 35 become “L”, and the precharge assist circuit 12 and the precharge circuit 14 connected to the bit line BL0 are turned off. Then, the word signal SWL1 generated by the row decoder 3 for the selected word line WL1 becomes “H”, after which a read operation of the memory cell 20 is begun. Since the precharge circuits 14 and 24 and the precharge assist circuits 12 and 22 are in off state at this point, the bit lines BL0 and BL1 are separated from reference voltages Vdr0 and Vdr1. Then, at time t5, the sense-amplifier activation signal VSA generated by the sense-amplifier-drive-signal generation circuit 34 becomes “H”, the sense amplifier 6 is activated, and then the cell voltage Vcell of the selected memory cell 20 and the external reference voltage Vdr0 applied to the bit line BL0 are compared and amplified at the sense amplifier 6. The sense amplifier 6 outputs “1” for Vcell>Vdr0 and “0” for Vcell≦Vdr0. In test mode, the external reference voltage Vdr0 is changed to detect the voltage Vdr0 when the output signal from the sense amplifier 6 changes from “1” to “0”, or vice versa, as the amount of the cell signal. As a result, the distribution of the amount of cell signals for the entire memory cell array 2 is measured.

The operation of the conventional semiconductor storage device will now be described below. FIG. 9 is a timing chart illustrating the operation of the conventional semiconductor storage device in test mode. As described above, the conventional semiconductor storage device does not have the precharge assist circuits 12 and 22 according to the first embodiment of the present invention. As such, no precharge assist signal VRME is illustrated in the timing chart.

In test mode, firstly, at time t1′, the chip enable signal VCE input to the CE control circuit 31 becomes “H” and the chip enters a standby state. A longer period of time is reserved for the chip enable signal CE to be in a standby state, compared to that of the normal read operation. This is because it will take a long time in test mode operation for precharging multiple bit lines at the same time before all of the bit lines are charged to a predetermined potential, as compared with the normal read operation. Then, the word signal SWL0 of the non-selected word line becomes “L” due to the word signal SWL generated by the row decoder 3. At the same time, the precharge signal VRM generated by the precharge-circuit-drive-signal generation circuit 35 becomes “H”, the transistor Q1 of the precharge circuit 14 turns on, and the bit line BL0 is precharged by the external reference voltage Vdr0 input to the precharge circuit 14 until time t2′.

Here, focusing on the precharge time, it will be apparent that the first embodiment of the present invention takes a shorter time for precharging than the conventional art. Specifically, the first embodiment of the present invention as illustrated in FIG. 8 takes a time of (t4−t1) for precharging, whereas (t2′−t1′) in the conventional art. From FIGS. 8 and 9, it can be seen that (t4−t1)<(t2′−t1′), and hence the precharging time is reduced in the first embodiment of the present invention as compared with the conventional art.

The subsequent operations are the same as the first embodiment and description thereof will be omitted.

According to the first embodiment described above, the potential of the bit line BL to which a non-selected memory cell is connected may be rapidly charged to Vdr−Vth1 by the precharge assist circuits 12 and 22 using the power supply voltage VDD before it is charged to the external reference voltage Vdr by the precharge circuits 14 and 24. Accordingly, this may achieve a significant reduction in time required for a rise in bit line potential in the test mode for measuring the distribution of the amount of cell signals in a memory cell array. As a result, high-speed measurement of the amount of cell signals may be achieved.

### Second Embodiment

A semiconductor storage device according to a second embodiment of the present invention will now be described below. The semiconductor device and its circuit configuration is generally the same as those illustrated in FIGS. 1 and 2. The semiconductor storage device according to the second embodiment is different from the first embodiment in that it does not have the precharge assist circuits 12 and 22 as indicated in the first embodiment, and that it reduces the time required for a rise in bit line potential using the dummy cell voltages Vdc applied to the dummy cell circuits 11 and 21. Hereinafter, the same reference numerals represent the same components as the first embodiment. A circuit configuration of the semiconductor storage device according to the second embodiment will be described in detail below with reference to the drawings.

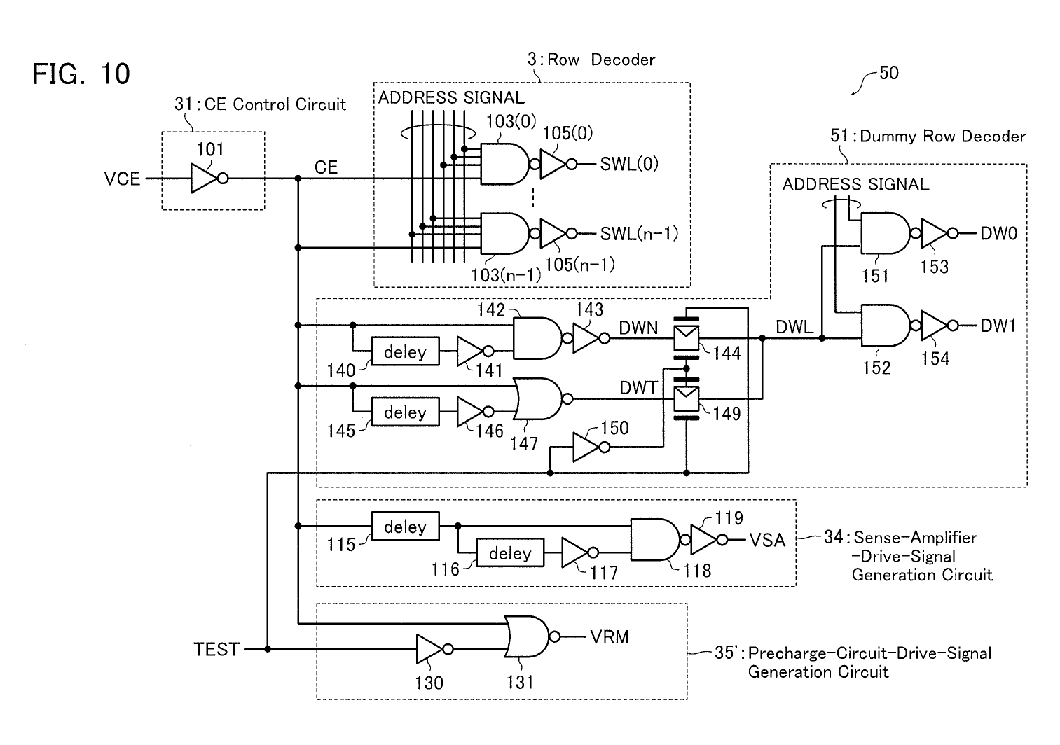

FIG. 10 illustrates an example circuit configuration according to the second embodiment. The semiconductor storage device 50 according to the second embodiment comprises: a CE control circuit 31 that generates a chip enable signal CE; a row decoder 3 that generates a word signal SWLi; a dummy row decoder 51 that generates a dummy word signal; a sense-amplifier-drive-signal generation circuit 34 that generates a sense-amplifier drive signal; and a precharge-circuit-drive-signal generation circuit 35′ that generates a precharge signal VRM. The CE control circuit 31, the row decoder 3, the sense-amplifier-drive-signal generation circuit 34, and the precharge-circuit-drive-signal generation circuit 35′ have the same functions as those described above in conjunction with FIGS. 4 and 5 and description thereof will be omitted.

The dummy row decoder 51 performs a NAND operation at a NAND gate 142 on a chip enable signal CE and another signal resulting from delaying the chip enable signal CE by a delay circuit 140 and then inverting it by an inverter 141, the output of which is in turn inverted at an inverter 143, thereby obtaining a signal DWN. In addition, at a NOR gate 147, it performs a NOR operation on the chip enable signal CE and another signal resulting from delaying the chip enable signal CE by a delay circuit 145 and then inverting it by an inverter 146, thereby obtaining a signal DWT.

Then, these signals DWN and DWT are input to a selection circuit that includes two CMOS transistors 144 and 149 as well as an inverter 150. A test initiation signal TEST is input to a connection node between the PMOS gate of the CMOS transistor 144 and the NMOS gate of the CMOS transistor 149. On the other hand, such a signal resulting from inverting the test initiation signal TEST by an inverter 150 is input to another connection node between the NMOS gate of the CMOS transistor 144 and the PMOS gate of the CMOS transistor 149. Under the control of the test initiation signal TEST, any of the signals DWN or DWT is output through the above-mentioned selection circuit, thereby obtaining a dummy word line signal DWL.

Thereafter, at NAND gates 151 and 152, a NAND operation is performed on the dummy word line signal DWL and an address signal from the address-signal generation circuit 7, the output of which is in turn inverted at inverters 153 and 154 to generate dummy word signals DW0 and DW1.

The operation of the semiconductor storage device according to the second embodiment will now be described in detail below. FIG. 11 is a timing chart illustrating the operation of the semiconductor storage device according to the second embodiment in test mode. Here, consider the case where the memory cell 20 connected to the bit line BL1 is read and an external reference voltage Vdr0 is applied to the bit line BL0. In addition, for the purposes of this description, it is assumed that the dummy cell voltage Vdc=0.4V, the external reference voltage Vdr0=0.7V, and the external reference voltage Vdr1=0V.

Firstly, at time t1, the chip enable signal VCE input to the CE control circuit 31 becomes “H” and the chip enters a standby state. Then, at time t2, dummy cell voltages Vdc are supplied to the dummy cell circuits 11 and 21, the dummy word signals DW0 and DW1 generated by the dummy row decoder 51 become “H”, and the transistors Q3 and Q4 turn on. The bit line BL0 and BL1 have a predetermined potential of, e.g., on the order of 0.3V, which is determined by the capacitance ratio of the capacitor C1 to the bit line.

At the same time, the word signal SWL0 generated by the row decoder 3 becomes “L” and the memory cell 10 becomes a non-selected memory cell. Then, at time t3, the precharge signal VRM generated by the precharge-circuit-drive-signal generation circuit 35′ becomes “H” and the transistor Q1 turns on, by which the bit line BL0 is precharged to 0.7V with Vdr0. On the other hand, when the transistor Q2 turns on, the bit line BL1 is discharged to 0V with the external reference voltage Vdr1. The time interval between t2 and t3 is several nanoseconds due to the capacitive coupling between the corresponding MOS capacitors.

Conventionally, the bit line BL0 must be precharged from 0V to 0.7V, which can be time-consuming. According to the second embodiment, however, since the bit line BL0 will already be charged with the dummy cell voltage Vdc to 0.3V, which is determined by the capacitance ratio of the capacitor C1 to the bit line, it is sufficient that the precharge circuit 14 should charge from 0.3V to 0.7V, achieving high-speed processing. Therefore, the second embodiment may also achieve faster processing than the conventional circuits.

Subsequently, at time t4, the dummy word signals DW0 and DW1 generated by the dummy row decoder 51 become “L” Then, at time t5, the precharge signal VRM generated by the precharge-circuit-drive-signal generation circuit 35′ becomes “L”. Then, the word signal SWL1 generated by the row decoder 3 becomes “H” and the memory cell 20 is selected, where the read operation is ready to begin. Since the precharge signal VRM is “L” at this moment, the transistors Q1 and Q2 are turned off and the bit lines BL0 and BL1 are separated from the reference voltages Vdr0 and Vdr1. At time t6, the sense-amplifier activation signal VSA generated by the sense-amplifier-drive-signal generation circuit 34 becomes “H” and the sense amplifier 6 is activated. The cell voltage Vcell of the selected memory cell 20 and the external reference voltage Vdr0 (0.7V in this example) applied to the bit line BL0 are compared and amplified at the sense amplifier 6. As a result, the sense amplifier 6 outputs “1” for Vcell>Vdr0 and “0” for Vcell≦Vdr0. The distribution of the amount of cell signals in the memory cell array 2 may be measured by changing Vdr0 and considering such Vdr0 as the amount of cell signals that is observed when the output transitions from “1” to “0” or vice versa.

According to the second embodiment, the bit line to which a non-selected memory cell is connected may be charged in advance to a predetermined potential using the dummy cell voltage Vdc before precharging it to the external reference voltage Vdr by a precharge circuit. Accordingly, this may achieve a reduction in time required for a rise in bit line potential in the test mode for measuring the distribution of the amount of cell signals in a memory cell array. As a result, high-speed measurement of the amount of cell signals can be achieved.

### Third Embodiment

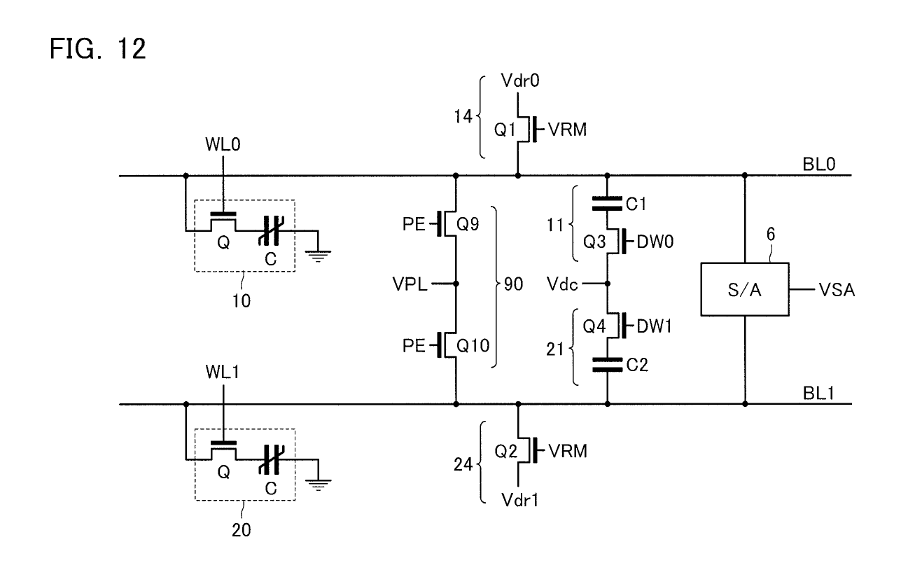

FIG. 12 illustrates a typical part of a pair of bit lines BL0, BL1 in a memory cell array 2 of a semiconductor storage device according to a third embodiment of the present invention. The semiconductor storage device according to the third embodiment is different from the above-mentioned first and second embodiments in that it has a stress reduction circuit and uses a stress reduction voltage VPL that is applied to the stress reduction circuit to reduce the time required for a rise in bit line potential. Note that hereinafter the same reference numerals represent the same components as the previous embodiments.

Referring first to FIG. 12, a circuit configuration of the semiconductor storage device according to the third embodiment of the present invention will be described in detail below. It is different from the above-mentioned circuit according to the second embodiment in that a stress reduction circuit 90 is provided between a pair of bit lines BL0, BL1, for applying a stress reduction voltage VPL to the bit lines in order to mitigate the stress on memory cells during the standby mode. For example, the stress reduction circuit 90 includes two NMOS transistors Q9 and Q10 connected in series in such a way that their drains are connected to each other. The two NMOS transistors Q9 and Q10 have respective source electrodes connected to the bit lines BL0 and BL1.

Other circuit configuration is the same as the first and second embodiments and description thereof will be omitted.

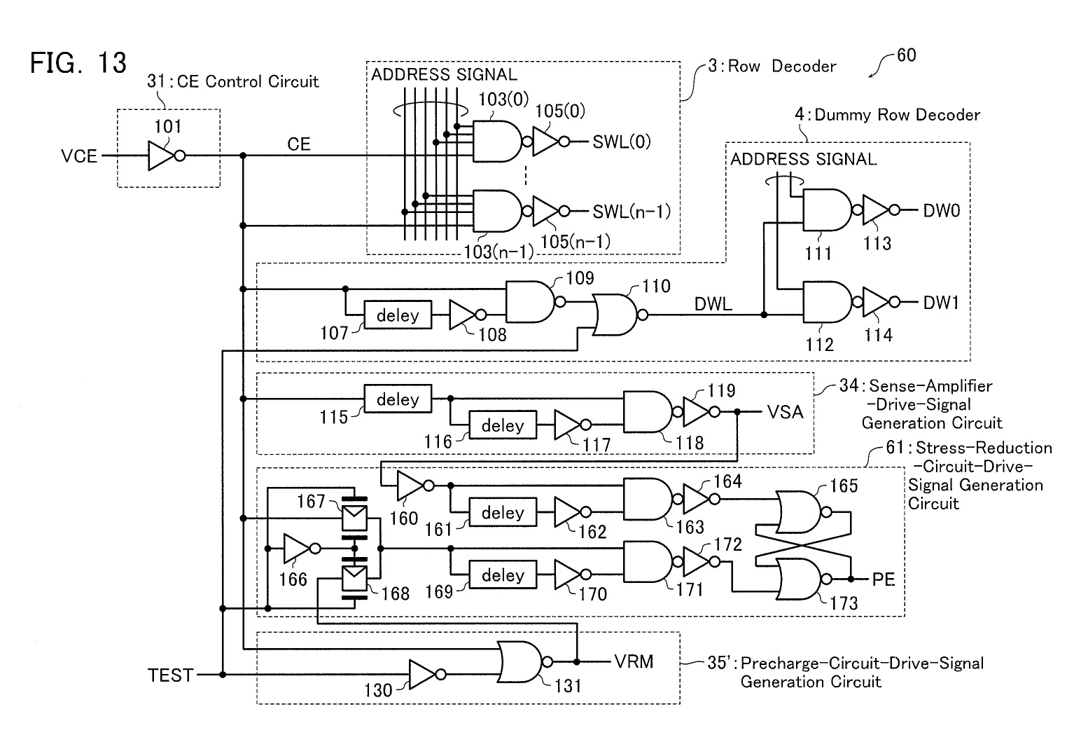

An example circuit configuration of the semiconductor storage device according to the third embodiment of the present invention will now be described below with reference to the drawings. FIG. 13 illustrates a specific circuit configuration of the semiconductor storage device according to the third embodiment. The semiconductor storage device 60 according to the third embodiment comprises: a CE control circuit 31 that generates a chip enable signal CE; a row decoder 3 that generates a word signal; a dummy row decoder 4 that generates a dummy word signal; a sense-amplifier-drive-signal generation circuit 34 that generates a sense-amplifier drive signal VSA; a stress-reduction-circuit-drive-signal generation circuit 61 that generates a stress reduction signal PE to drive the stress reduction circuit 90; and a precharge-circuit-drive-signal generation circuit 35′ generating precharge signals VRM to drive precharge circuits 14 and 24. The CE control circuit 31, the row decoder 3, the dummy row decoder 4, the sense-amplifier-drive-signal generation circuit 34, and the precharge-circuit-drive-signal generation circuit 35′ have the same functions as those described above in conjunction with FIGS. 4 and 5 and description thereof will be omitted.

The stress-reduction-circuit-drive-signal generation circuit 61 performs a NAND operation at a NAND gate 163 on a signal resulting from inverting a sense-amplifier activation signal VSA by an inverter 160 and another signal resulting from delaying that signal by a delay circuit 161 and then inverting it by an inverter 162, the output of which is in turn inverted by an inverter 164 to generate the resulting signal. The resulting signal is input to the set input of a flip-flop circuit including two NOR gates 165 and 173.

In addition, at a selection circuit including two CMOS transistors 167 and 168 as well as an inverter 166, the stress-reduction-circuit-drive-signal generation circuit 61 controls a chip enable signal CE input to the drain of one CMOS transistor 167 and a precharge signal VRM input to the drain of the other CMOS transistor 168 by a test initiation signal TEST to output any of the chip enable signal CE or the precharge signal VRM.

The stress-reduction-circuit-drive-signal generation circuit 61 performs a NAND operation at a NAND gate 171 on the output signal from the selector circuit and another signal resulting from delaying that output signal by a delay circuit 169 and then inverting it by an inverter 170, the output of which is in turn inverted by an inverter 172 to generate the resulting signal. The resulting signal is input to the reset input of the above-mentioned flip-flop circuit.

The stress-reduction-circuit-drive-signal generation circuit 61 generates a stress reduction signal PE delayed by a certain amount of time than the chip enable signal CE through the flip-flop circuit.

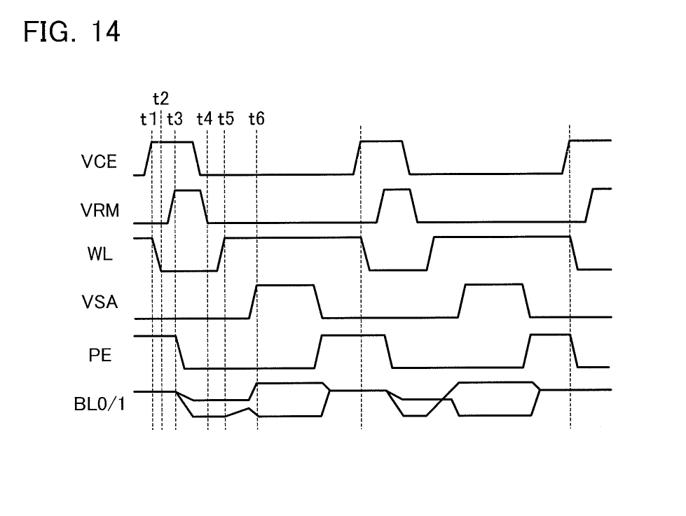

The operation of the semiconductor storage device according to the third embodiment will now be described in detail below with reference to the drawings. FIG. 14 is a timing chart illustrating the operation of the semiconductor device according to the third embodiment in test mode. Here, consider the case where the memory cell 20 connected to the bit line BL1 is read and an external reference voltage Vdr0 is applied to the bit line BL0. In addition, for the purposes of this description, it is assumed that the stress reduction voltage VPL=0.8V, the external reference voltage Vdr0 applied to the bit line BL0=0.7V, and the external reference voltage Vdr1 applied to the bit line BL1=0V.

Firstly, at time t1, the chip enable signal VCE input to the CE control circuit 31 becomes “H” and the chip enters a standby state. During the standby state, the stress-reduction-circuit drive signal PE generated by the stress-reduction-circuit-drive-signal generation circuit 61 has a potential of “H” and the transistors Q9 and Q10 in the stress reduction circuit 90 turn on, thereby charging the respective potentials of the bit lines BL0 and BL1 to 0.8V. Then, at time t2, the word signal SWL0 generated by the row decoder 3 becomes “L” and the memory cell 10 connected to the bit line BL0 becomes a non-selected memory cell. Then, at time t3, the precharge signal VRM generated by the precharge-circuit-drive-signal generation circuit 35′ becomes “H” and the transistors Q1 and Q2 turn on. As a result, the bit line BL0 is discharged to 0.7V with the external reference voltage Vdr0 and the bit line BL1 is discharged to 0V with the external reference voltage Vdr1. At the same time, the potential of the stress reduction signal PE is made “L” through the stress-reduction-circuit-drive-signal generation circuit 61, the transistors Q9 and Q10 are turned off, and then the stress reduction circuit 90 is separated from the bit lines BL0 and BL1.

Conventionally, the bit line BL0 must be charged from 0V to 0.7V by the precharge circuit 14, which can be time-consuming. According to the third embodiment of the present invention, however, since the bit line BL0 will already be charged to 0.8V by the stress reduction circuit 90, it is sufficient that the bit line BL0 should be discharged from 0.8V to 0.7V, achieving a faster test mode operation. On the other hand, while the bit line BL1 operates in such a way that it is once charged from 0V to 0.8V with the stress reduction voltage VPL and then discharged again to 0V, this embodiment may still achieve a faster test mode operation than the conventional circuits because discharging will complete in less time than charging.

Subsequently, at time t4, the precharge signal VRM generated by the precharge-circuit-drive-signal generation circuit 35′ becomes “L” and the external reference voltages Vdr0 and Vdr1 are separated from the bit lines BL0 and BL1. Then, at time t5, the word signal SWL1 generated by the row decoder 3 becomes “H” and the memory cell 20 is selected, where the read operation is ready to begin. Then, at time t6, the sense-amplifier activation signal VSA generated by the sense-amplifier-drive-signal generation circuit 34 becomes “H” and the sense amplifier 6 is activated. The cell voltage Vcell of the memory cell 20 and the external reference voltage Vdr0 (0.7V in this example) of the bit line BL0 are compared and amplified at the sense amplifier 6. As a result, the sense amplifier 6 outputs “1” for Vcell>Vdr0 and “0” for Vcell≦Vdr0. In test mode, the distribution of the amount of cell signals in the memory cell array may be measured by changing Vdr0 and considering such Vdr0 as the amount of cell signals that is observed when the output transitions from “1” to “0” or vice versa.

According to the third embodiment of the present invention, the time required for a rise in bit line potential may be reduced in test mode for measuring the distribution of the amount of cell signals in a memory cell array, by once increasing the bit line potential with the stress reduction voltage VPL that is supplied to the stress reduction circuit and then rapidly discharging it to the external reference voltage Vdr. As a result, high-speed measurement of the distribution of the amount of cell signals can be achieved in test mode operation.

### [Others]

While embodiments of the present invention have been described, the present invention is not intended to be limited to the disclosed embodiments and various changes, additions or the like may be made thereto without departing from the spirit of the invention. For example, it should be understood that the memory cells are not limited to the 1T/1C-type configuration and may have 2T/2C-type or other configurations as well.

What is claimed is:

1. A semiconductor storage device comprising:
a plurality of memory cells, each comprising a capacitor configured to retain data;
a plurality of word lines configured to be used in selecting the memory cells;
a first bit line configured to be used in reading a signal in one of the memory cells selected by the word lines;
a precharge circuit configured to precharge a second bit line paired with the first bit line connected to the selected one of the memory cells, by applying to the second bit line an external reference voltage for comparison with a voltage in the first bit line caused by selection of the memory cell;
a precharge assist circuit connected to the second bit line in parallel with the precharge circuit, the precharge assist circuit is configured to charge the second bit line to a predetermined potential by using a power supply voltage; and
a sense amplifier connected to the pair of bit lines, the sense amplifier configured to sense and amplify a potential of a bit line connected to a memory cell selected by the word lines.

2. The semiconductor storage device of claim 1, wherein
the second bit line is charged to a voltage lower than the external reference voltage by the precharge assist circuit before being precharged by the precharge circuit.

3. The semiconductor storage device of claim 1, wherein
the precharge assist circuit comprises a first transistor with a first threshold voltage, and a second transistor with a second threshold voltage lower than the first threshold voltage, the first and second transistors being connected in series, and
the power supply voltage is connected to one terminal of the first transistor.

4. The semiconductor storage device of claim 3, wherein
the second bit line is charged to a voltage lower than the external reference voltage by the precharge assist circuit before being precharged by the precharge circuit.

5. The semiconductor storage device of claim 3, wherein
the precharge circuit is activated according to a change in logic of a first drive signal;
the precharge assist circuit is activated according to a change in logic of a second drive signal;
the first transistor comprises a gate configured to receive the second drive signal; and
the second transistor comprises a gate configured to receive the external reference voltage.

6. The semiconductor storage device of claim 5, wherein
the logic of second drive signal is configured to change before the logic of the first drive signal changes, in a test mode for measuring a distribution of the amount of cell signals in the memory cells.

7. The semiconductor storage device of claim 5, wherein
the second bit line is charged to a voltage lower than the external reference voltage by the precharge assist circuit before being precharged by the precharge circuit.

8. The semiconductor storage device of claim 1, wherein
the precharge circuit is activated according to a change in logic of a first drive signal;
the precharge assist circuit is activated according to a change in logic of a second drive signal; and
logic of the second drive signal is configured to change before the logic of the first drive signal changes, in a test mode for measuring a distribution of the amount of cell signals in the memory cells.

9. The semiconductor storage device of claim 5, further comprising:
a chip enable controller configured to generate a chip enable signal; and
a drive-signal generator configured to generate the first drive signal and the second drive signal according to the chip enable signal,
wherein the drive-signal generator is configured to generate the first drive signal based on a signal resulting from delaying the chip enable signal by a predetermined time.

10. The semiconductor storage device of claim 1, wherein
the precharge assist circuit is configured to start an operation before the precharge circuit starts operating.

11. The semiconductor storage device of claim 10, wherein
the second bit line is charged to a voltage lower than the external reference voltage by the precharge assist circuit before being precharged by the precharge circuit.

12. The semiconductor storage device of claim 10, wherein
the precharge assist circuit comprises a first transistor with a first threshold voltage, and a second transistor with a second threshold voltage lower than the first threshold voltage, the first and second transistors being connected in series, and
the power supply voltage is connected to one terminal of the first transistor.

13. The semiconductor storage device of claim 1, wherein
the amount of cell signals in the memory cells is detected by changing the external reference voltage in a test mode for measuring a distribution of the amount of cell signals in the memory cells.

14. The semiconductor storage device of claim 13, wherein
the precharge assist circuit is configured to start an operation before the precharge circuit starts an operation.

15. The semiconductor storage device of claim 13, wherein
the second bit line is charged to a voltage lower than the external reference voltage by the precharge assist circuit before being precharged by the precharge circuit.

16. A semiconductor storage device comprising:
a plurality of memory cells, each comprising a capacitor configured to retain data;
a plurality of word lines configured to be used in selecting the memory cells;
a first bit line configured to be used in reading a signal in one of the memory cells selected by the word lines;
a precharge circuit configured to precharge a second bit line paired with the first bit line connected to the selected one of the memory cells, by applying to the second bit line an external reference voltage for comparison with a voltage in the first bit line caused by selection of the memory cell;
a dummy cell circuit comprising dummy cells connected in series between the pair of bit lines, each of the dummy cells comprising one transistor and one capacitor; and
a sense amplifier connected to the pair of bit lines, the sense amplifier configured to sense and amplify a potential of a bit line connected to a memory cell selected by the word lines,
wherein the second bit line is charged to a predetermined potential with a dummy-cell reference voltage supplied to the dummy cells before being charged by the precharge circuit.

17. The semiconductor storage device of claim 16, wherein
the precharge circuit is activated by a first drive signal;
a transistor in the dummy cell circuit is configured to switch to a conducting state by a third drive signal; and
logic of the third drive signal is configured to change before logic of the first drive signal changes, in a test mode for measuring a distribution of the amount of cell signals in the memory cells.

18. The semiconductor storage device of claim 16, wherein
the amount of cell signals in the memory cells is detected by changing the external reference voltage in a test mode for measuring a distribution of the amount of cell signals in the memory cells.

19. A semiconductor storage device comprising:
a plurality of memory cells, each comprising a capacitor configured to retain data;
a plurality of word lines configured to be used in selecting the memory cells;
a first bit line configured to be used in reading a signal in one of the memory cells selected by the word lines;
a precharge circuit precharging a second bit line paired with the first bit line connected to the selected one of the memory cells, by applying to the second bit line an external reference voltage for comparison with a voltage in the first bit line caused by selection of the memory cell;
a stress reduction circuit comprising two Metal Oxide Semiconductor(MOS) transistors connected in series between the pair of bit lines; and
a sense amplifier connected to the pair of bit lines, the sense amplifier configured to sense and amplify a potential of a bit line connected to a memory cell selected by the word lines,
the second bit line being charged to a predetermined potential with a stress reduction voltage supplied to the stress reduction circuit before being charged by the precharge circuit.

20. The semiconductor storage device of claim 19, wherein
the precharge circuit is configured to discharge the second bit line to a voltage lower than the stress reduction voltage.
